(19) United States
(12) Patent Application Publication
(10) Pub. No.: US 2026/0106055 A1
(43) Pub. Date: Apr. 16, 2026

(54) HIGH SPEED TWIN-AXIAL CABLE

(71) Applicant: Amphenol Corporation, Wallingford, CT (US)

(72) Inventors: Matthew S. Wright, Madison, CT (US); Russell K. Isch, Coventry, CT (US); Timothy M. Tassmer, Wallingford, CT (US)

(73) Assignee: Amphenol Corporation, Wallingford, CT (US)

(21) Appl. No.: 19/114,354

(22) PCT Filed: Sep. 22, 2023
(86) PCT No.: PCT/US2023/033451

§ 371 Date: Mar. 21, 2025

Related U.S. Application Data
(60) Provisional application No. 63/409,374, filed on Sep. 23, 2022.

(51) Int. Cl. H01B 11/00; H01B 3/44; H05K 9/00

(52) U.S. Cl. CPC H01B 11/002; H01B 3/441; H05K 9/0098

(57) ABSTRACT

A twin-axial cable is provided. The twin-axial cable includes a first conductor having a length along a longitudinal direction and a second conductor parallel to the first conductor along the longitudinal direction. The twin-axial cable further includes a primary insulation including a first core and a second core, the first core surrounding the first conductor and the second core surrounding the second conductor, each of the first core and the second core being shaped as a horizontal cylindrical segment comprising a surface extending along the longitudinal direction. The surfaces of the first core and the second core are disposed in contact with one another, and a ratio between a first distance, c, between the first conductor and the second conductor to a distance, a, between the first conductor and an edge of the primary insulation in the plane and opposite the second conductor is 1.8 or less.

### CROSS REFERENCE TO RELATED APPLICATIONS

This application claims the benefit under 35 U.S.C. § 119(e) of U.S. Provisional Patent Application Ser. No. 63/409,374, titled “HIGH SPEED TWIN-AXIAL CABLE,” filed on Sep. 23, 2022, which is incorporated herein by reference in its entirety.

### FIELD OF THE INVENTION

This disclosure relates generally to differential signal transmission and more specifically to twin-axial cables able to carry high-frequency signals and methods of making the same.

### BACKGROUND

Cables have been used within or between electronic devices for carrying high-speed signals. Cables, for example, may provide lower signal loss over relatively long distances. Additionally, cables may be bent or twisted for routing around obstacles or fitting within tight spaces.

Cables may be constructed by encircling one or more conductors within the cable by a conducting braid or film, which may serve as an electromagnetic shield. Shielding of the conductors of a cable may enable the cables to be positioned closely together in a bundle or a ribbon without interference between the signals carried in each cable. Additionally, the conducting braid or film may set the impedance of the conductors to a desired level.

In some cables, called twin-axial cables (sometimes referred to as “twinax”), two conductors, each surrounded by electrically insulating material, may be held tightly together and then surrounded by a shield and, possibly other layers, such as an external jacket. Some twin-axial cables may additionally include one or more wires in contact with the shield, sometimes called drain wires. The two insulated conductors may be used to carry a differential signal, which further reduces interference between signals in closely spaced cables. The drain wires may be connected to ground at either or both ends of the cable, thereby ensuring that the shield is grounded.

### SUMMARY

Some embodiments of the technology described herein are directed to a cable. The cable includes a first conductor having a length along a longitudinal direction and a second conductor having a length parallel to the first conductor along the longitudinal direction. The first conductor and the second conductor are separated by a first distance along a line perpendicular to the longitudinal direction. The cable also includes a primary insulation comprising a first core and a second core, the first core surrounding the first conductor along its length and the second core surrounding the second conductor along its length, each of the first core and the second core being shaped as a horizontal cylindrical segment comprising a surface extending along the longitudinal direction. The surfaces of the first core and the second core face one another, and a ratio between the first distance and a second distance, the second distance being between the first conductor and an edge of the primary insulation along the line, is less than or equal to 1.8.

Optionally, the primary insulation has a dielectric constant with a value from 1.4 to 2.4.

Optionally, the primary insulation comprises polyethylene.

Optionally, the cable further includes a conductive shield surrounding the first core and the second core.

Optionally, the cable further includes a first conductive drain wire disposed within the conductive shield.

Optionally, the first conductive drain wire is disposed adjacent a central position where the surfaces of the first and second cores are in contact with one another.

Optionally, the cable further includes a first conductive drain wire and a second conductive drain wire disposed outside of the conductive shield, wherein the first conductor and the second conductor are disposed between the first conductive drain wire and the second conductive drain wire along the line.

Optionally, the cable further includes a secondary insulation surrounding the primary insulation, wherein the secondary insulation is inside the conductive shield.

Optionally, the surfaces of the first core and the second core are non-interlocking surfaces.

Optionally, the surfaces of the first core and the second core are un-fused.

Some embodiments of the technology described herein are directed to a method of manufacturing a cable from a first insulated wire comprising a first conductor extending along a longitudinal direction surrounded by a first core comprising primary insulator material, the first core having a cylindrical shape extending along the longitudinal direction and a second insulated wire comprising a second conductor extending along the longitudinal direction and surrounded by a second core, the second core comprising the primary insulator material, the second core having a cylindrical shape extending along the longitudinal direction. The method includes removing a segment of the primary insulator material from the first core and from the second core so that the first core and the second core are shaped as horizontal cylindrical segments each comprising a surface extending along the longitudinal direction parallel to the conductor, and placing the surface of the first core in contact with the surface of the second core so that the first conductor and the second conductor are disposed parallel to each other and within a shared plane.

Optionally, removing the segment of the primary insulator material from the first core and from the second core comprises removing a segment having a size configured to cause, when the surfaces of the first core and the second core are placed in contact, a ratio between a first distance between the first conductor and the second conductor to a second distance between the first conductor and an edge of the first core in a direction along a line between centers of the first conductor and the second conductor and perpendicular to the longitudinal direction is 1.8 or less.

Optionally, the method further includes wrapping a conductive shield around the first insulated wire and the second insulated wire.

Optionally, the method further includes, prior to wrapping the conductive shield, placing a first conductive drain wire in contact with the first core and the second core and at a lateral position between the first conductor and the second conductor.

Optionally, the method further includes, after wrapping the conductive shield, placing a first conductive drain wire adjacent the first core and a second conductive drain wire adjacent the second core, the first conductive drain wire being disposed opposite the second conductive drain wire with the first core and the second core disposed along the line between the first conductive drain wire and the second conductive drain wire.

Optionally, removing the segment of the primary insulator material from the first core and the second core comprises cutting the primary insulator material.

Optionally, cutting the primary insulator material comprises cutting the primary insulator material using a blade.

Optionally, removing the segment of the primary insulator material from the first core and the second core comprises removing the segment using a laser.

The features described herein in the various embodiments may be used, separately or together in any combination, in any of the embodiments discussed herein.

### BRIEF DESCRIPTION OF DRAWINGS

Various aspects and embodiments of the present technology disclosed herein are described below with reference to the accompanying figures. It should be appreciated that the figures are not necessarily drawn to scale. Items appearing in multiple figures may be indicated by the same reference numeral. For the purposes of clarity, not every component may be labeled in every figure.

FIG. 1A is a cross-sectional view of an exemplary twin-axial cable, in accordance with some embodiments of the technology described herein.

FIG. 1B is a cross-sectional view of another exemplary twin-axial cable including marked dimensions, in accordance with some embodiments of the technology described herein.

FIG. 2 is a cross-sectional view of an exemplary twin-axial cable comprising insulative cores having curved interfaces where the insulative cores come into contact with each other, in accordance with some embodiments of the technology described herein.

FIG. 3 is a cross-sectional view of an exemplary twin-axial cable comprising a secondary insulator surrounding the insulative cores, in accordance with some embodiments of the technology described herein.

FIG. 4 is a cross-sectional view of an exemplary a twin-axial cable comprising a drain wire located inside the shield layer, in accordance with some embodiments of the technology described herein.

FIG. 5 is a cross-sectional view of an exemplary twin-axial cable comprising drain wires located outside the shield layer, in accordance with some embodiments of the technology described herein.

FIG. 6 is a schematic, perspective view of an exemplary method of manufacturing a twin-axial cable, in accordance with some embodiments of the technology described herein.

### DETAILED DESCRIPTION

Described herein are twin-axial cables for improved differential signaling, particularly for high-speed signals, and techniques for manufacturing the same. These twin-axial cables include two parallel conductors, each conductor surrounded by an insulator core. The insulator cores may be shaped as truncated cylinders with a surface extending along the length of the conductors. The insulator cores may be held to abut at these surfaces. The insulator cores may be shaped to reduce the spacing between centers of the conductors, and this spacing may be reduced without compressing the insulator or fusing the insulator cores to each other.

In some embodiments, the cable may be formed by shaping the insulator cores after they are formed around the two parallel conductors as cylinders. Segments of the insulator cores may be removed (e.g., by a blade, by a laser) to create surfaces along the length of the insulator cores. The two insulator cores may then be brought into contact such that the insulator cores are in contact at the surfaces. In some examples, the surface may be flat, and the flat surface of one insulator core may be in contact with the flat surface of the other insulator core.

Cables as described herein may provide for desirable and uniform electrical properties. Abutting the insulated conductors at surfaces formed by truncating the cylindrical shape of the insulator core reduces the distance between the two parallel conductors while maintaining a constant dielectric constant in the insulative material between the two parallel conductors (e.g., by preventing compression of the insulator core material). This configuration may increase coupling between the two parallel conductors in contrast to a conventional cable design with fully cylindrical insulators. The separation between the conductors and the surrounding cable shield may be the same, resulting in the impedance of the cable being more influenced by the distance between the conductors and less influenced by the distance between the conductors and the cable shield in comparison to a cable of conventional design. As the separation between conductors may be more readily controlled than the separation between the conductors and the cable shield, particularly if the cable is bent or twisted, there is less variability in electrical properties. As variations in electrical properties, such as impedance, may cause reflections or otherwise disrupt high speed signals carried by the cable, reducing variation improves high-speed performance of the cable.

Electrical properties, such as impedance, may be uniform along the length of the cable. Impedance may vary, for example, by less than 5% over the length of the cable, even for cables that are long, such as on the order of 3 meters. Alternatively or additionally, these properties may be uniform with respect to manipulation of the cable. For example, the insertion loss deviation (ILD) may be less than 1% for a cable, carrying a signal 56 Gbps, even when bent from a straight configuration into a loop with a diameter of, for example, 10 mm.

The inventors theorize that cables with structures as described herein and/or manufactured according to methods as described herein may provide more uniform electrical properties, both over the length of the cable and when the cable is bent, than cables in which similar spatial relationships are achieved in other ways. Twin-axial cables, for example, may be made using foam insulators surrounding the two conductors, where the foam is created by pumping or injecting air bubbles into a material that will trap the air bubbles. Foam cores generally perform better under bending than solid insulators. The inventors theorize that better performance results from the relationship with the shield material. If the dielectric is stiff and does not yield, the stress is distributed over a larger area of cable, resulting in increased noise.

In twin-axial cables with foam insulators, the material properties (e.g., the dielectric constant) at any location within the foam is dependent on the amount and size of the air bubbles. Conventional twin-axial cables may be formed such that the foam core has a circular cross section, but that cross section may be distorted as the two conductors are brought closer together and a portion of the foam core between the two conductors is compressed. The inventors have recognized and appreciated that such compression of the foam core changes the dielectric constant of the foam across the foam between the signal conductors, as air pockets in the foam are compressed or eliminated. A cable in which the foam is sufficiently soft such that the spacing between conductors can be readily changed by compressing the foam may result in poorly controlled impedance along the length of a cable. Such variation may lead to large insertion loss deviation (ILD) or other undesired electrical properties of the cable.

Further, even circular foam cores manufactured using the best processes available may not meet industry performance expectations for signal to noise ratio without additional structures. In some cables with foam cores, the signal to noise ratio is improved by reducing coupling to the shield relative to the coupling between the conductors by adding a secondary, solid dielectric extrusion over the circular foam cores.

Accordingly, the inventors have developed methods for reducing the distance between the signal conductors of a differential signal pair that does not require compressing soft foam insulators between the signal conductors. Such techniques may use foam and may provide the performance and bend resistance benefits of foam, without need for additional extrusion layers. These techniques may provide further bend resistance as a result of an interface between insulator cores with less stress and therefore less noise upon bending.

Some embodiments of the technology described herein are directed to a cable including a first conductor and a second conductor having a length along a longitudinal direction, the second conductor being parallel to the first conductor along the longitudinal direction.

In some embodiments, the cable includes a primary insulation including a first core and a second core. The first core surrounds the first conductor, and the second core surrounds the second conductor, and each of the first core and the second core are shaped as a horizontal cylindrical segment comprising a surface (e.g., a flat, substantially flat, or concave surface) extending along the longitudinal direction. The surfaces of the first core and the second core face one another and the insulating cores may be held with those surfaces abutting each other. In examples in which the surfaces are flat, they may be parallel to one another and in contact over a relatively large percentage of each surface, such as greater than 90%.

In some embodiments, the surfaces of the first core and the second core are non-interlocking surfaces. The inventors theorize that having the two sides of the twinax interlocked, fused together or otherwise adhered to each other reduces the ability of the insulator cores to yield to localized applied stresses, such that better performance of the cable may be achieved by having separate surfaces abutting without being bound together. Techniques as described herein may be applied to implement cables with non-interlocked and/or un-fused surfaces where the two insulated conductors interface.

In some embodiments, a ratio between a first distance along a line between the first conductor and the second conductor to a second distance along that line between the first conductor and an edge of the primary insulation in a direction opposite the second conductor is limited to reduce a distance between the first and second conductor and improve coupling between the first and second conductor. For example, the ratio between the first distance and the second distance may be less than or equal to 1.8 in some embodiments.

In some embodiments, the primary insulation has a dielectric constant with a value from 1.1 to about 2.5, such as between 1.4 and 2.4 or between 1.4 to 2.15. Alternatively or additionally, in some embodiments, the primary insulation can be formed out of extruded polyethylene.

In some embodiments, the cable further includes a conductive shield surrounding the first core and the second core. The conductive shield electrically isolates the first conductor and second conductor from external sources of electromagnetic noise and/or serves as a ground reference for the differential signal carried by the conductors within the first core and the second core. In some embodiments, the cable includes a secondary insulation surrounding the conductive shield.

The cable, in some embodiments, also includes a first conductive drain wire disposed within the conductive shield. The first conductive drain may be disposed between the first conductor and the second conductor, in some embodiments. The drain wire, for example, may be aligned with the interface between the first core and the second core. The drain wire, for example, may be disposed on exterior surfaces of the first core and the second core. Additionally, in some embodiments, the cable may further include a second conductive drain wire. The second drain wire may be within the conductive shield and may be on an opposite side of the interface between the first core and the second core. Alternatively or additionally, the cable may include one or more conductive drain wires disposed outside of the conductive shield. In some embodiments, one or more drain wires outside of the shield may be disposed on a line between the first conductor and the second conductor.

Some embodiments of the technology described herein are directed to a method of manufacturing a cable. The method includes forming a first insulated wire by surrounding a first conductor extending along a longitudinal direction with a first core comprising primary insulator material, the first core having a cylindrical shape extending along the longitudinal direction. Additionally, the method includes forming a second insulated wire by surrounding a second conductor extending along the longitudinal direction with a second core comprising the primary insulator material, the second core having a cylindrical shape extending along the longitudinal direction. Thereafter, the method includes removing a segment of the primary insulator material from the first core and the second core so that the first core and the second core are shaped as horizontal cylindrical segments each comprising a surface (e.g., flat, substantially flat, or concave) extending along the longitudinal direction parallel to the conductor. The surface of the first core is then placed in contact with the surface of the second core so that the first conductor and the second conductor are disposed parallel to each other.

In some embodiments, removing the segment of the primary insulator material comprises cutting the primary insulator material using a blade. Alternatively, in some embodiments, removing the segment of the primary insulator material comprises removing the segment using a laser.

Following below are more detailed descriptions of various concepts related to, and embodiments of, a cable or techniques for manufacturing a cable. It should be appreciated that various aspects described herein may be implemented in any of numerous ways. Examples of specific implementations are provided herein for illustrative purposes only. In addition, the various aspects described in the embodiments below may be used alone or in any combination and are not limited to the combinations explicitly described herein.

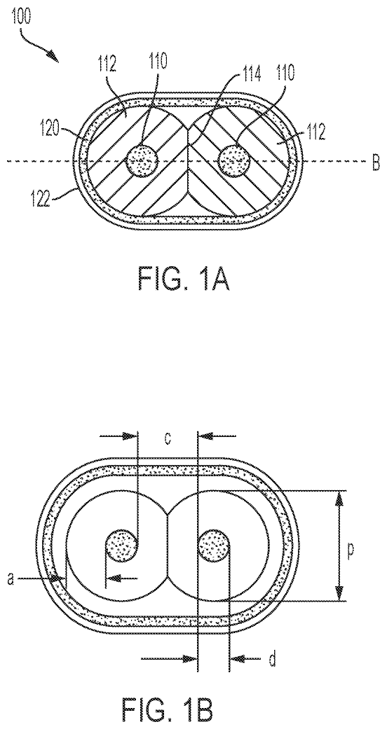

FIG. 1A shows a cross-sectional view of an illustrative example of a cable 100, in accordance with some embodiments of the technology described herein. A cable may have a substantially uniform cross section taken at any location along the longitudinal dimension of the cable. In this example, the cable includes two conductors 110 disposed parallel to one another. The conductors 110 are separated along a line B. Each conductor 110 may have a diameter, labeled as distance d in the example of FIG. 1B, within a range from 0.005 inches to 0.02 inches, or within any suitable range of values within that range.

In some embodiments, each conductor is surrounded by primary insulation 112, comprising a first core and a second core, each of the first core and the second core surrounding one of the two conductors 110, respectively. The primary insulation 112 is formed, in some embodiments, from a foam insulator. For example. the primary insulation 112 may be formed from an extruded polyethylene foam or fluorinated polymer foam. In some embodiments, the primary insulation 112 may have a dielectric constant within a range from 1.1 to 2.5, or within any range of values within that range, such as 1.4 to 2.4. In examples in which the insulator is foamed, the foam may be relatively hard, such as greater than 20 Shore A.

Each core of the primary insulation cores may be shaped as a horizontal cylindrical segment, the segment having a relatively flat surface 114. In some embodiments, each core of the primary insulation 112 may have an outer radius, labeled as distance a in the example of FIG. 1B, within a range from 0.15 mm to 0.60 mm, or within any suitable range of values within that range. Additionally, each core of the primary insulation 112 may have a diameter, labeled as distance p in the example of FIG. 1B, within a range from 0.4 mm to 1.8 mm, or within any suitable range of values within that range. The radius and diameter may reflect a measurement along a line that does not intersect the surface 114.

In some embodiments, the first core and the second core of the primary insulation 112 are disposed so that their surfaces 114 face each other. The surfaces 114 may abut each other at one or more locations. As shown in the example of FIG. 1A, the surface 114 may be a flat or substantially flat surface. In embodiments in which the surfaces 114 are flat, the surfaces 114 may be in contact with one another over substantially their full extent, such as greater than 90% of their area. In some embodiments, the surfaces 114 may be non-interlocking surfaces. In some embodiments, the first core and the second core of the primary insulation 112 may first be formed with a circular cross section (e.g., by an extrusion process around the conductors 110). In such embodiments, the surface 114 may be formed thereafter by removing a segment of the primary insulation 112 from the first core and the second core. For example, the segment may be removed using a blade or a laser.

In some embodiments, removing a segment from the first core and the second core and creating surface 114 allows for the two conductors 110 to be disposed closely together without substantially compressing the primary insulation 112 between the two conductors 110. The reduced distance between the two conductors 110 within the plane B, labelled as distance c in the example of FIG. 1B, enables an improved electromagnetic coupling between signals transmitted through the two conductors 110. Additionally, the conductors 110 may be brought more closely together in the example of FIG. 1A without compressing the material of the primary insulation. In embodiments where the primary insulation comprises a foam insulator, compression of the primary insulation would increase the dielectric constant of the primary insulation as air bubbles within the foam would be compressed. Thus, the configuration of the example of FIG. 1A enables a reduced distance between the two conductors 110 without altering the material and electrical properties of the primary insulation 112 disposed between the conductors 110, enabling improved overall performance of the cable.

In some embodiments, the conductors 110 and primary insulation 112 may be surrounded by a conductive shield layer 120. The conductive shield layer 120 may act as an electromagnetic shield, preventing or mitigating effects of electromagnetic interference on signals transmitted through cable 100. The conductive shield layer 120 may be, in some embodiments, formed out of any suitable conductive material (e.g., copper, aluminum, etc.). The shield layer, for example, may be a metal film and may be deposited on a polymer film or other substrate. The shield layer may be wrapped helically around the insulator cores or may be wrapped to form a longitudinal joint. In some embodiments, a covering 122 may further surround the conductive shield layer 120. The covering 122 may be formed of an electrically insulating material (e.g., a suitable plastic) and provide protection (e.g., mechanical protection) for the components of the cable 100.

In some embodiments, the distance c between the two conductors 110 and the distance a between a conductor of the two conductors 110 and an outer radius of the respective core in a direction along the line B and away from the other conductor may be set to decrease sensitivity of the impedance of the cable to variations in the distance a. For example, a ratio between the distance c and the distance a may be chosen to improve coupling between the two conductors 110 while maintaining the separation between the conductors and the shield layer 120. In some embodiments, the ratio between the distance between the first conductor and the second conductor (distance c) to a distance between the first conductor and an edge of the primary insulation along line B and in a direction opposite the second conductor (distance a) may be less than or equal to 1.8.

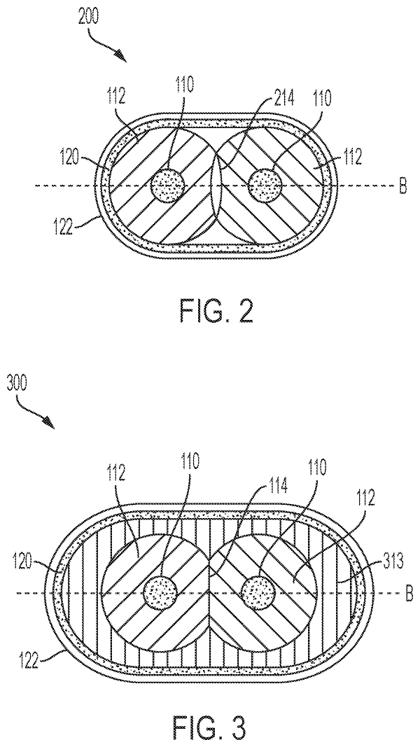

Alternative arrangements of cable 100 are shown in the embodiments of FIGS. 2-5. FIG. 2 shows a cross-sectional view of an illustrative example of a cable 200 comprising insulative cores 112 having curved surfaces 214 where the cylindrical insulative cores are truncated. As in the example of FIG. 1A and 1B, the insulative cores come into contact with each other at one or more locations along the truncated surfaces. As shown in the example of FIG. 2, the curved surfaces 214 are concave (e.g., they curve inward) rather than being flat or substantially flat as in the example of FIG. 1A. Shaping the surfaces between the cores of the primary insulation 112 as curved surfaces 214 may provide an additional reduction in the distance between the two conductors 110. When the two cores of the primary insulation 112 are brought together (not pictured), the portions of the primary insulation 112 at the top and bottom of the curved surface 214 may compress, so that the curved surfaces 214 are brought into contact with one another, forming a substantially flat interface with a reduced distance between the conductors 110.

In some embodiments, the cable may include a secondary insulation, as shown in the example of FIG. 3 and in accordance with some embodiments of the technology described herein. Cable 300 includes secondary insulation 313 surrounding the primary insulation 112. The secondary insulation 313 may encapsulate the first and second cores of the primary insulation 112 and may be formed of a suitable insulating material. For example, secondary insulation 313 may be formed of an insulating foam or insulative material that may be the same or different than the insulative material used to form the primary insulation. For example, because the secondary insulation 313 may further reduce the sensitivity of the impedance of the cable on variations in the separation between shield layer 120 and conductors 110, secondary insulation 313 may be softer than primary insulation 112 without materially impacting ILD of the cable.

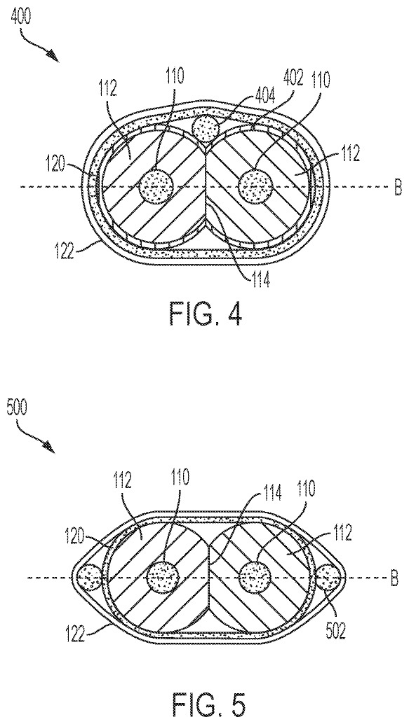

In some embodiments, one or more drain wires may be included in the cable, as shown in the examples of FIGS. 4 and 5 and in accordance with some embodiments of the technology described herein. The drain wires may be connected to ground and provide a mechanism for making a ground connection to the shield layer 120, for example. In the example of FIG. 4, cable 400 includes a first drain wire 404 disposed inside of the conductive shield layer 120. The first drain wire 404 may be disposed between the first core and the second core and above the line B. In this example, first drain wire 404 is aligned with the interface between surfaces 114 of the first and second insulative cores 112. In some embodiments, an additional covering 402 may surround the primary insulation 112 and separate the primary insulation 112 from the first drain wire 404. It should be appreciated that a second drain wire (not pictured) could additionally be disposed below the line B. The drain wires may be symmetrically positioned around the cable (e.g., opposite the first drain wire 404 within the conductive shield layer 120). The first and second drain wires, for example, may be symmetrical with respect to the line B. The drain wires alternatively or additionally may be symmetrically positioned with respect to the conductors 110 of the cable. In other examples, drain wires may be distributed around the cable, without necessarily being symmetrically placed.

In some embodiments, and as shown in the example of FIG. 5, the cable may include one or more drain wires 502 located outside of the conductive shield layer 120. The drain wires 502 may be disposed generally along the line B on opposite sides of the cable with the conductors 110 between the drain wires 502. Alternatively, it should be appreciated that drain wires 502 may be disposed outside of the conductive shield layer 120 and above and below line B (e.g., positioned between the first core and the second core of the primary insulation 112 as in the example of FIG. 4).

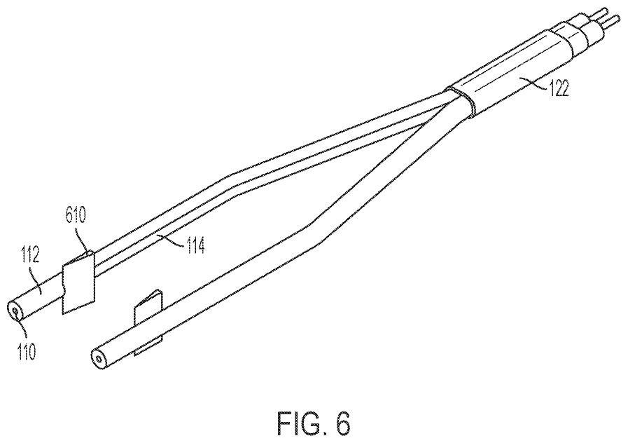

FIG. 6 shows an illustrative example of a method of manufacturing a cable, in accordance with some embodiments of the technology described herein. The primary insulation 112 may first be formed around the conductors 110 with a circular cross section. For example, the primary insulation 112 may be formed using an extrusion process that forms an extruded cylinder with conductors 110 centered in the cylinder. Thereafter, blades 610 may remove a segment of the primary insulation 112 to form the surfaces 114 on each of two insulated conductors. It should be appreciated that in some embodiments, a laser or other suitable cutting tool may be used in place of blades 610 to remove the segment of the primary insulation 112.

In some embodiments, after the segment is removed from each of the first core and the second core of the primary insulation 112, the first core and the second core may be brought together such that the surfaces 114 of each are brought into contact. Thereafter, the first core and the second core of the primary insulation may be surrounded by a conductive shield layer and/or covering 122 to form a cable.

In some examples, the insulated conductors may be held together by a shield layer or layer of other material wrapped around the insulated conductors. In those examples the surfaces 114 are not fixed with respect to each other in a longitudinal direction. As the cable is bent, stress may be low at the interface between surfaces 114 of the two insulated conductors, providing stable electrical characteristics and low noise, even when the cable is bent.

Further, by removing a portion of the insulator core of each insulated wire, the conductors of the insulated wires are separated, center-to-center, by a distance that is less than the diameter of the unmodified insulated wires. In some examples, the ratio of the distance between the conductors (e.g. dimension c in FIG. 1B) and the distance between a conductor and the outside of the primary insulator where the primary insulation has not been cut away (e.g. dimension a in FIG. 1B) may be 1.8 or less. This positioning can be achieved without compressing the remaining insulation of the insulated wires. That insulation may have relatively uniform properties, such as dielectric constant. As a specific example, the dielectric constant of the insulator of the insulator cores between the conductors is not materially increased by compression. The effective dielectric constant of the insulative material in a region between the conductors, for example, may deviate from the effective dielectric constant of the insulative material outside that region by less than 5% and in some examples by less than 2% or less than 1%.

It should be understood that various alterations, modifications, and improvements may be made to the structures, configurations, and methods discussed above, and are intended to be within the spirit and scope of the invention disclosed herein.

For example, it was described in connection with FIG. 6 that a cable could be manufactured by extruding insulator around conductors that are formed into a twin-axial cable. It is not a requirement that the cores be extruded in the same facility or as part of the same process in which the insulated wires are assembled into a cable. The insulated wires, for example, may be manufactured at a first time and spooled. At a second time, the spooled insulated wires may be processed to remove a segment of their primary insulation and then formed into a twin-axial cable.

As another example, insulated wires of a twin-axial cable may be held stably with respect to one another by wrapping a shield layer around the cores. The shield layer may have an adhesive layer and/or may be overwrapped with a polymer film, for example, to provide additional mechanical integrity to the cable. Alternatively or additionally, a secondary insulation 313 may be used to hold the insulated wires together. Other attachment mechanisms may be used. For example, adhesive may be applied on surfaces 114.

Further, although advantages of the present invention are indicated, it should be appreciated that not every embodiment of the invention will include every described advantage. Some embodiments may not implement any features described as advantageous herein. Accordingly, the foregoing description and attached drawings are by way of example only.

It should be understood that some aspects of the present technology may be embodied as one or more methods, and acts performed as part of a method of the present technology may be ordered in any suitable way. Accordingly, embodiments may be constructed in which acts are performed in an order different than shown and/or described, which may include performing some acts simultaneously, even though shown and/or described as sequential acts in various embodiments.

Various aspects of the present invention may be used alone, in combination, or in a variety of arrangements not specifically discussed in the embodiments described in the foregoing and is therefore not limited in its application to the details and arrangement of components set forth in the foregoing description or illustrated in the drawings. For example, aspects described in one embodiment may be combined in any manner with aspects described in other embodiments.

Further, terms denoting direction have been used, such as “left”, “right”, “top” or “bottom.” These terms are relative to the illustrated embodiments, as depicted in the drawings, for ease of understanding. It should be understood that the components as described herein may be used in any suitable orientation.

Use of ordinal terms such as “first,” “second,” “third,” etc., in the description and the claims to modify an element does not by itself connote any priority, precedence, or order of one element over another, or the temporal order in which acts of a method are performed, but are used merely as labels to distinguish one element or act having a certain name from another element or act having a same name (but for use of the ordinal term) to distinguish the elements or acts.

Definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

As used herein in the specification and in the claims, the phrase “at least one,” in reference to a list of one or more elements, should be understood to mean at least one element selected from any one or more of the elements in the list of elements, but not necessarily including at least one of each and every element specifically listed within the list of elements and not excluding any combinations of elements in the list of elements. This definition also allows that elements may optionally be present other than the elements specifically identified within the list of elements to which the phrase “at least one” refers, whether related or unrelated to those elements specifically identified.

As used herein in the specification and in the claims, the phrase “equal” or “the same” in reference to two values (e.g., distances, widths, etc.) means that two values are the same within manufacturing tolerances. Thus, two values being equal, or the same, may mean that the two values are different from one another by ±5%.

The phrase “and/or,” as used herein in the specification and in the claims, should be understood to mean “either or both” of the elements so conjoined, i.e., elements that are conjunctively present in some cases and disjunctively present in other cases. Multiple elements listed with “and/or” should be construed in the same fashion, i.e., “one or more” of the elements so conjoined. Other elements may optionally be present other than the elements specifically identified by the “and/or” clause, whether related or unrelated to those elements specifically identified. Thus, as a non-limiting example, a reference to “A and/or B”, when used in conjunction with open-ended language such as “comprising” can refer, in one embodiment, to A only (optionally including elements other than B); in another embodiment, to B only (optionally including elements other than A); in yet another embodiment, to both A and B (optionally including other elements); etc.

As used herein in the specification and in the claims, “or” should be understood to have the same meaning as “and/or” as defined above. For example, when separating items in a list, “or” or “and/or” shall be interpreted as being inclusive, i.e., the inclusion of at least one, but also including more than one, of a number or list of elements, and, optionally, additional unlisted items. Only terms clearly indicated to the contrary, such as “only one of” or “exactly one of,” or, when used in the claims, “consisting of,” will refer to the inclusion of exactly one element of a number or list of elements. In general, the term “or” as used herein shall only be interpreted as indicating exclusive alternatives (i.e. “one or the other but not both”) when preceded by terms of exclusivity, such as “either,” “one of,” “only one of,” or “exactly one of.” “Consisting essentially of,” when used in the claims, shall have its ordinary meaning as used in the field of patent law.

Also, the phraseology and terminology used herein is for the purpose of description and should not be regarded as limiting. Use of terms such as “including,” “comprising,” “comprised of,” “having,” “containing,” and “involving,” and variations thereof herein, is meant to encompass the items listed thereafter and equivalents thereof as well as additional items.

The terms “approximately,” “about,” “relatively,” and “substantially” if used herein may be construed to mean within ±20% of a target value in some embodiments, within ±10% of a target value in some embodiments, within ±5% of a target value in some embodiments, and within ±2% of a target value in some embodiments. The terms “approximately,” “about,” “relatively,”and “substantially”may equal the target value.

The term “substantially” if used herein may be construed to mean within 95% of a target value in some embodiments, within 98% of a target value in some embodiments, within 99% of a target value in some embodiments, and within 99.5% of a target value in some embodiments. In some embodiments, the term “substantially” may equal 100% of the target value.

1. A cable, comprising:
a first conductor having a length along a longitudinal direction;
a second conductor having a length parallel to the first conductor along the longitudinal direction, wherein the first conductor and the second conductor are separated by a first distance along a line perpendicular to the longitudinal direction; and
a primary insulation comprising a first core and a second core, the first core surrounding the first conductor along its length and the second core surrounding the second conductor along its length, each of the first core and the second core being shaped as a horizontal cylindrical segment comprising a surface extending along the longitudinal direction, wherein:
the surfaces of the first core and the second core face one another; and
a ratio between the first distance and a second distance, the second distance being between the first conductor and an edge of the primary insulation along the line, is less than or equal to 1.8.

2. The cable of claim 1, wherein the primary insulation has a dielectric constant with a value from 1.4 to 2.4.

3. The cable of claim 1, wherein the primary insulation comprises polyethylene.

4. The cable of claim 1, further comprising a conductive shield surrounding the first core and the second core.

5. The cable of claim 4, further comprising a first conductive drain wire disposed within the conductive shield.

6. The cable of claim 5, wherein the first conductive drain wire is disposed adjacent a central position where the surfaces of the first and second cores are in contact with one another.

7. The cable of claim 4, further comprising a first conductive drain wire and a second conductive drain wire disposed outside of the conductive shield, wherein the first conductor and the second conductor are disposed between the first conductive drain wire and the second conductive drain wire along the line.

8. The cable of claim 4, further comprising a secondary insulation surrounding the primary insulation, wherein the secondary insulation is inside the conductive shield.

9. The cable of claim 1, wherein the surfaces of the first core and the second core are non-interlocking surfaces.

10. The cable of claim 1, wherein the surfaces of the first core and the second core are un-fused.

11. A method of manufacturing a cable from a first insulated wire comprising a first conductor extending along a longitudinal direction surrounded by a first core comprising primary insulator material, the first core having a cylindrical shape extending along the longitudinal direction and a second insulated wire comprising a second conductor extending along the longitudinal direction and surrounded by a second core, the second core comprising the primary insulator material, the second core having a cylindrical shape extending along the longitudinal direction, the method comprising:
removing a segment of the primary insulator material from the first core and from the second core so that the first core and the second core are shaped as horizontal cylindrical segments each comprising a surface extending along the longitudinal direction parallel to the first and second conductor; and
placing the surface of the first core in contact with the surface of the second core so that the first conductor and the second conductor are disposed parallel to each other and within a shared plane.

12. The method of claim 11, wherein removing the segment of the primary insulator material from the first core and from the second core comprises removing a segment having a size configured to cause, when the surfaces of the first core and the second core are placed in contact, a ratio between a first distance between the first conductor and the second conductor to a second distance between the first conductor and an edge of the first core in a direction along a line between centers of the first conductor and the second conductor and perpendicular to the longitudinal direction is 1.8 or less.

13. The method of claim 12, further comprising:
wrapping a conductive shield around the first insulated wire and the second insulated wire.

14. The method of claim 13, further comprising:
prior to wrapping the conductive shield, placing a first conductive drain wire in contact with the first core and the second core and at a lateral position between the first conductor and the second conductor.

15. The method of claim 13, further comprising:
after wrapping the conductive shield, placing a first conductive drain wire adjacent the first core and a second conductive drain wire adjacent the second core, the first conductive drain wire being disposed opposite the second conductive drain wire with the first core and the second core disposed along the line between the first conductive drain wire and the second conductive drain wire.

16. The method of claim 11, wherein removing the segment of the primary insulator material from the first core and the second core comprises cutting the primary insulator material.

17. The method of claim 16, wherein cutting the primary insulator material comprises cutting the primary insulator material using a blade.

18. The method of claim 11, wherein removing the segment of the primary insulator material from the first core and the second core comprises removing the segment using a laser.
